(19) United States
(12) Patent Application Publication
(10) Pub. No.: US 2025/0280672 A1
(43) Pub. Date: Sep. 4, 2025

(54) DISPLAY PANELS

(71) Applicant: Wuhan China Star Optoelectronics Semiconductor Display Technology Co., Ltd., Wuhan, Hubei (CN)

(72) Inventor: Liang MA, Wuhan, Hubei (CN)

(21) Appl. No.: 18/556,672

(22) PCT Filed: Jun. 29, 2023
(86) PCT No.: PCT/CN2023/103595

§ 371 Date: Oct. 22, 2023

(30) Foreign Application Priority Data
Nov. 23, 2022 (CN) 202211478158.0

(51) Int. Cl. H10K 59/131; H10K 39/34

(52) U.S. Cl. CPC H10K 59/131; H10K 39/34

(57) ABSTRACT

The present application provides a display panel. The display panel includes: a photosensitive device, where the photosensitive device includes a switching element, a first photosensitive element, and a second photosensitive element. The first photosensitive element includes a first electrode, a first photosensitive portion, and a first protection electrode. The second photosensitive element includes a second electrode, a second photosensitive portion, and a second protective electrode. The switching element includes a source and a drain. The first electrode is connected to the second electrode, and the first photosensitive portion and the second photosensitive portion are both connected to either the source or the drain.

### TECHNICAL FIELD

The present application relates to the field of display technologies, and more particularly to display panels.

### BACKGROUND

A Fingerprint recognition has become a function that most of display terminals such as a mobile phone, a tablet computer, a notebook computer, and the like are equipped with. Currently, the fingerprint recognition of the display device is gradually changing from capacitive fingerprint recognition to optical fingerprint recognition. The optical fingerprint recognition is to image a user's fingerprint by refraction and reflection of light, and then to recognize a fingerprint feature by an image recognition method. The optical fingerprint recognition has characteristics of higher imaging resolution, easies image recognition, and the like, and can be arranged under a display screen to form an underscreen fingerprint recognition.

A conventional photosensitive device detects a light using a photosensitive element that is a semiconductor device converting a received light signal into an electrical signal. However, with improvement of the pixel resolution, an in-plane light emitting unit may squeeze the area of the photosensitive element, resulting in a lower amount of the photoelectric signal and affecting detection sensitivity of the fingerprint recognition.

### SUMMARY

The present application provides a display panel to solve the technical problems that the area of the photosensitive element is smaller, resulting in a lower amount of the photoelectric signal, and affecting the detection sensitivity.

The present application provides a display panel, including: at least one photosensitive device, including a switching element, a first photosensitive element, and a second photosensitive element; where the display panel further includes:

a substrate;

a first conductive layer disposed on the substrate and including a first electrode and a second electrode connected to the first electrode;

a photosensitive layer disposed on one side of the first conductive layer away from the substrate and including a first photosensitive portion corresponding to the first electrode and a second photosensitive portion corresponding to the second electrode, where the first photosensitive portion and the second photosensitive portion are disposed at intervals, and the photosensitive layer further includes a metal oxide semiconductor;

an insulating layer disposed between the first conductive layer and the photosensitive layer;

a second conductive layer disposed on one side of the photosensitive layer away from the substrate and including a first protection electrode and a second protection electrode, where the first protection electrode is electrically connected to the first photosensitive portion, and the second protection electrode is electrically connected to the second photosensitive portion; and

a third conductive layer disposed on one side of the second conductive layer away from the substrate and including a source and a drain of the switching element, where the first protection electrode and the second protection electrode are both electrically connected to the source or the drain of the switching element;

where the first photosensitive element includes the first electrode, the first photosensitive portion, and the first protection electrode, and the second photosensitive element includes the second electrode, the second photosensitive portion, and the second protective electrode.

Optionally, in some embodiments of the present application, the display panel further includes:

a first active layer disposed between the substrate and the photosensitive layer and including a first active portion of the switching element, where the source and the drain of the switching element are both electrically connected to the first active portion, and the first active portion includes either a polysilicon semiconductor or a polysilicon semiconductor.

Optionally, in some embodiments of the present application, the photosensitive device further includes: storage capacitor;

the first conductive layer further includes a first capacitor electrode of the storage capacitor, where the first capacitor electrode is electrically connected to both the first electrode and the second electrode; and

the third conductive layer further includes a second capacitor electrode of the storage capacitor, where the second capacitor electrode is electrically connected to both the first protection electrode and the second protection electrode, and at least partially overlaps the first capacitor electrode.

Optionally, in some embodiments of the present application, the display panel further includes: a fourth conductive layer including a conductive portion, where an orthographic projection of the conductive portion on the substrate at least partially overlaps an orthographic projection of at least one of the first electrode and the second electrode on the substrate.

Optionally, in some embodiments of the present application, the metal oxide semiconductor of the photosensitive layer has an electron mobility greater than or equal to 10 cm²/Vs, and the insulating layer has a thickness of 5 nm to 15 nm.

Optionally, in some embodiments of the present application, the display panel further includes: a pixel driving circuit including both a first driving transistor and a second driving transistor;

the display panel further includes:

a second active layer disposed between the substrate and the photosensitive layer and including a second active portion of the first driving transistor, where the second active portion includes a polysilicon semiconductor;

a third active layer disposed between the second active layer and the photosensitive layer and including a third active portion of the second driving transistor, where the third active portion includes a metal oxide semiconductor; and

a conductive layer disposed between the second active layer and the third active layer and including a second gate of the first driving transistor, where the second gate at least partially overlaps the second active portion;

where the second conductive layer further includes a third gate of the second driving transistor, the third gate at least partially overlapping the third active portion.

Optionally, in some embodiments of the present application, the first active portion includes a polysilicon semiconductor;

the second active layer further includes the first active portion, and the conductive layer further includes a first gate of the switching element, the first gate at least partially overlapping the first active portion.

Optionally, in some embodiments of the present application, the first active portion includes a metal oxide semiconductor.

the third active layer further includes the first active portion, the conductive layer further includes a fourth gate of the switching element, and the second conductive layer further includes a first gate of the switching element, where the fourth gate at least partially overlaps the first active portion, and the first gate at least partially overlaps the first active portion.

Optionally, in some embodiments of the present application, the display panel further includes: a plurality of light emitting units arranged in a plurality of rows in a first direction and arranged in a plurality of columns in a second direction;

where a plurality of intersecting regions are formed between the plurality of rows of light emitting units and the plurality of columns of light emitting units, and each of the intersecting regions is provided with at most one first photosensitive element or one second photosensitive elements.

Optionally, in some embodiments of the present application, the first photosensitive element and the second photosensitive element are respectively located in two adjacent ones of the intersecting regions located on the same side of the same light emitting unit.

Optionally, in some embodiments of the present application, the display panel further includes: a plurality of the photosensitive devices;

where a plurality of the first photosensitive elements and a plurality of the second photosensitive elements in the same row are alternately arranged, a plurality of the first photosensitive elements and a plurality of the second photosensitive elements in the same column are alternately arranged, and each of the first photosensitive elements is connected in parallel with one of the second photosensitive elements, which is located in the same row and in the same side as the first photosensitive element and adjacent to the first photosensitive element, or each of the first photosensitive elements is connected in parallel with one of the second photosensitive elements, which is located in the same column and in the same side as the first photosensitive element and adjacent to the first photosensitive element; or

a plurality of the first photosensitive elements and a plurality of the second photosensitive elements in the same row are alternately arranged, the first photosensitive elements or the second photosensitive elements are in the same column, and each of the first photosensitive elements is connected in parallel with one of the second photosensitive elements, which is located in the same row and in the same side as the first photosensitive element and adjacent to the first photosensitive element.

Optionally, in some embodiments of the present application, the photosensitive device further includes a third photosensitive element;

where the third photosensitive element includes a third electrode, a third protection electrode, and a third photosensitive portion between the third electrode and the third protection electrode; the third electrode and the first electrode are located in the same layer and connected to each other, the third photosensitive portion and the first photosensitive portion are located in the same layer and arranged at intervals, and the third protection electrode is connected to either the source or the drain; and

the first photosensitive element, the second photosensitive element, and the third photosensitive element are respectively located in three of the intersection regions at three vertices of the same light emitting unit.

Another embodiment of the present application further involves a display panel, including: at least one photosensitive device, including a switching element, a first photosensitive element, and a second photosensitive element; where the display panel further includes:

a substrate;

a first conductive layer disposed on the substrate and including a first electrode and a second electrode connected to the first electrode;

a photosensitive layer disposed on one side of the first conductive layer away from the substrate and including a first photosensitive portion corresponding to the first electrode and a second photosensitive portion corresponding to the second electrode, where the first photosensitive portion and the second photosensitive portion are disposed at intervals, and the photosensitive layer further includes a metal oxide semiconductor;

an insulating layer disposed between the first conductive layer and the photosensitive layer;

a second conductive layer disposed on one side of the photosensitive layer away from the substrate and including a first protection electrode and a second protection electrode, where the first protection electrode is electrically connected to the first photosensitive portion, and the second protection electrode is electrically connected to the second photosensitive portion; and

a third conductive layer disposed on one side of the second conductive layer away from the substrate and including a source and a drain of the switching element, where the first protection electrode and the second protection electrode are both electrically connected to the source or the drain of the switching element;

where the first photosensitive element includes the first electrode, the first photosensitive portion, and the first protection electrode, and the second photosensitive element includes the second electrode, the second photosensitive portion, and the second protective electrode;

the display panel further includes:

a first active layer disposed between the substrate and the first conductive layer and including a first active portion of the switching element, where a source and a drain of the switching element are electrically connected to the first active portion;

where the display panel further includes: a plurality of light emitting units arranged in a plurality of rows in a first direction and arranged in a plurality of columns in a second direction;

where a plurality of intersecting regions are formed between the plurality of rows of light emitting units and the plurality of columns of light emitting units, and each of the intersecting regions is provided with at most one first photosensitive element or one second photosensitive elements.

Optionally, in some embodiments of the present application, the photosensitive device further includes: a storage capacitor including a first capacitor electrode and a second capacitor electrode at least partially overlapping the first capacitor electrode;

the first capacitor electrode is electrically connected to both the first electrode and the second electrode; and

the second capacitor electrode is electrically connected to both the first protection electrode and the second protection electrode, and at least partially overlapping the first capacitor electrode.

Optionally, in some embodiments of the present application, the display panel further includes: a fourth conductive layer including a conductive portion, where an orthographic projection of the conductive portion on the substrate at least partially overlaps an orthographic projection of at least one of the first electrode and the second electrode on the substrate.

Optionally, in some embodiments of the present application, the metal oxide semiconductor of the photosensitive layer has an electron mobility greater than or equal to 10 cm²/Vs, and the insulating layer has a thickness of 5 nm to 15 nm.

Optionally, in some embodiments of the present application, the display panel further includes: a pixel driving circuit including both a first driving transistor and a second driving transistor;

the display panel further includes:

a second active layer disposed between the substrate and the photosensitive layer and including a second active portion of the first driving transistor, where the second active portion includes a polysilicon semiconductor;

a third active layer disposed between the second active layer and the photosensitive layer and including a third active portion of the second driving transistor, where the third active portion includes a metal oxide semiconductor; and

a conductive layer disposed between the second active layer and the third active layer and including a second gate of the first driving transistor, where the second gate at least partially overlaps the second active portion;

where the second conductive layer further includes a third gate of the second driving transistor, the third gate at least partially overlapping the third active portion.

Optionally, in some embodiments of the present application, the first active portion includes a polysilicon semiconductor;

the second active layer further includes the first active portion, and the conductive layer further includes a first gate of the switching element, the first gate at least partially overlapping the first active portion.

Optionally, in some embodiments of the present application, the first active portion includes a metal oxide semiconductor.

the third active layer further includes the first active portion, the conductive layer further includes a fourth gate of the switching element, and the second conductive layer further includes a first gate of the switching element, where the fourth gate at least partially overlaps the first active portion, and the first gate at least partially overlaps the first active portion.

Optionally, in some embodiments of the present application, the first photosensitive element and the second photosensitive element are respectively located in two adjacent ones of the intersecting regions located on the same side of the same light emitting unit.

### Beneficial Effects

The present application provides a display panel. The display panel includes: at least one photosensitive device, where the photosensitive device includes the switching element, the first photosensitive element, and the second photosensitive element. The first photosensitive element includes the first electrode, the first photosensitive portion, and the first protection electrode, and the second photosensitive element includes the second electrode, the second photosensitive portion, and the second protective electrode. Since the first electrode is connected to the second electrode, and the first photosensitive portion and the second photosensitive portion are both connected to either the source or the drain of the switching element, the first photosensitive element and the second photosensitive element are designed in parallel to increase the photosensitive area of the photosensitive device, thereby improving the amount of the photoelectric signal and the detection sensitivity. Additionally, since the first electrode and the second electrode are disposed at the same layer and the first photosensitive portion and the second photosensitive portion are disposed at the same layer, the film layer structure of the photosensitive device is simplified. Further, since the insulating layer is provided between the first electrode and the first photosensitive portion, the barrier difference between the first electrode and the first photosensitive portion can be reduced, thereby allowing electron tunneling to form a conductive path. Similarly, since the insulating layer is provided between the second electrode and the second photosensitive portion, the barrier difference between the second electrode and the second photosensitive portion can be reduced, thereby allowing electron tunneling to form a conductive path. Therefore, the photosensitive performance of the photosensitive device can be improved.

### BRIEF DESCRIPTION OF THE DRAWINGS

In order to more clearly illustrate the technical solutions in embodiments of the present application, the accompanying drawings depicted in the description of the embodiments will be briefly described below. It will be apparent that the accompanying drawings in the following description are merely some embodiments of the present application, and other drawings may be obtained from these drawings without creative effort by those skilled in the art.

FIG. 1 is a schematic diagram of a first structure of a display panel according to the present application.

FIG. 2 is a schematic circuit diagram of a photosensitive device according to the present application.

FIG. 3 is a schematic diagram of a second structure of a display panel according to the present application.

FIG. 4 is a schematic diagram of a third structure of a display panel according to the present application.

FIG. 5 is a schematic diagram of a fourth structure of a display panel according to the present application.

FIG. 6 is a schematic diagram of a fifth structure of a display panel according to the present application.

FIG. 7 is a schematic diagram of a sixth structure of a display panel according to the present application.

FIG. 8 is a schematic diagram of a seventh structure of a display panel according to the present application.

FIG. 9 is a schematic diagram of an eighth structure of a display panel according to the present application.

FIG. 10 is a schematic diagram of a ninth structure of a display panel according to the present application.

FIG. 11 is a first plan view of a display panel according to the present application.

FIG. 12 is a second plan view of a display panel according to the present application.

FIG. 13 is a third plan view of a display panel according to the present application.

### DETAILED DESCRIPTION

Technical solutions in embodiments of the present application will be clearly and completely described below in conjunction with drawings in the embodiments of the present application. Obviously, the described embodiments are only a part of embodiments of the present application, rather than all the embodiments. Based on the embodiments in the present application, all other embodiments obtained by those skilled in the art without creative work fall within the protection scope of the present application.

In the description of the present application, it should be understood that the terms “first” and “second” are for illustrative purposes only and are not to be construed as indicating or imposing a relative importance or implicitly indicating the number of technical features indicated. Thus, a feature that limited by “first” and “second” may expressly or implicitly include at least one of the features, and therefore cannot be construed as a limitation on the present application. Additionally, it should be noted that the terms “connected to” and “connection” should be understood in a broad sense, unless otherwise clearly specified and defined. For example, it can be a mechanical connection, or an electrical connection; it can be directly connected or indirectly connected through an intermediary, it can also be the connection between two elements. Those ordinary skilled in the art can understand the specific meanings of the above terms in the present application according to specific situations.

The present application provides a display panel, which is described in detail below. It should be noted that the description order of the following embodiments of the present application is not intended to limit the preferred order of the embodiments.

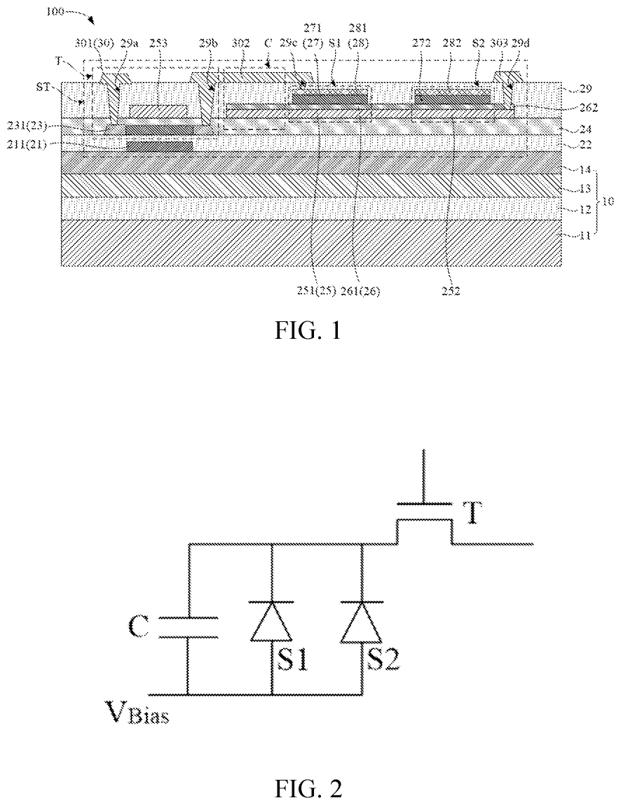

Please refer to FIG. 1, which is a schematic diagram of a first structure of a display panel according to the present application. In some embodiments of the present application, the display panel 100 includes at least one photosensitive device ST. The photosensitive device ST includes a switching element T, a first photosensitive element S1, and a second photosensitive element S2.

The display panel 100 further includes a substrate 10, a first conductive layer 25, an insulating layer 26, a photosensitive layer 27, a second conductive layer 28, and a third conductive layer 30.

The first conductive layer 25 is disposed on the substrate 10. The first conductive layer 25 includes a first electrode 251 and a second electrode 252 connected to the first electrode 251.

A photosensitive layer 27 is disposed on one side of the first conductive layer 25 away from the substrate 10. The photosensitive layer 27 includes a first photosensitive portion 271 corresponding to the first electrode 251 and a second photosensitive portion 272 corresponding to the second electrode 252. The photosensitive layer 27 includes a metal oxide semiconductor. The first photosensitive portion 271 and the second photosensitive portion 272 are provided at intervals.

An insulating layer 26 is disposed between the first conductive layer 25 and the photosensitive layer 27. For example, the insulating layer 26 includes a first insulating portion 261 and a second insulating portion 262. The first insulating portion 261 is located at least between the first electrode 251 and the first photosensitive portion 271. The second insulating portion 262 is located at least between the second electrode 252 and the second photosensitive portion 272.

A second conductive layer 28 is disposed on one side of the photosensitive layer 27 away from the substrate 10. The second conductive layer 28 includes a first protective electrode 281 and a second protective electrode 282. The first protection electrode 281 is electrically connected to the first photosensitive portion 271. The second protection electrode 282 is electrically connected to the second photosensitive portion 272.

A third conductive layer 30 is disposed on one side of the second conductive layer 28 away from the substrate 10. The third conductive layer 30 includes a source 301 and a drain 302 of the switching element T. The first protection electrode 281 and the second protection electrode 282 are both connected to either the source 301 or the drain 302. For example, the first protection electrode 281 and the second protection electrode 282 are both connected to the source 301. For another example, both the first protection electrode 281 and the second protection electrode 282 are both connected to the drain 302.

The first photosensitive element S1 includes the first electrode 251, the first insulating portion 261, the first photosensitive portion 271, and the first protective electrode 281. The second photosensitive element S2 includes the second electrode 252, the second insulating portion 262, the second photosensitive portion 272, and the second protective electrode 282.

The first electrode 251 may be directly connected to the second electrode 252. That is, the first electrode 251 and the second electrode 252 are designed as an integrated structure. The first electrode 251 may also be connected to the second electrode 252 by either a bridge line or a via hole, which is not specifically limited in the present application. In each of the following embodiments of the present application, that the first electrode 251 is directly connected to the second electrode 252 is taken as an example for illustration, but cannot be understood as a limitation of the present application.

In the embodiments of the present application, the photosensitive device ST includes at least two photosensitive elements, i.e., a first photosensitive element S1 and a second photosensitive element S2, respectively. Since the first electrode 251 is connected to the second electrode 252, and the first protection electrode 281 and the second protection electrode 282 are both connected to either the source 301 or the drain 302, so that parallel connection between the first photosensitive element S1 and the second photosensitive element S2 is implemented to increase the photosensitive area of the photosensitive device ST, thereby improving the amount of the photoelectric signal and the detection sensitivity. Additionally, since the first electrode 251 and the second electrode 252 are disposed at the same layer, the first photosensitive portion 271 and the second photosensitive portion 272 are disposed at the same layer, and the first protection electrode 281 and the second protection electrode 282 are disposed at the same layer, the film layer structure of the photosensitive device ST is simplified. Further, since the first insulating portion 261 is provided between the first electrode 251 and the first photosensitive portion 271, the barrier difference between the first electrode 251 and the first photosensitive portion 271 can be reduced, thereby allowing electron tunneling to form a conductive path. Similarly, since the second insulating portion 262 is provided between the second electrode 252 and the second photosensitive portion 272, the barrier difference between the second electrode 252 and the second photosensitive portion 272 can be reduced, thereby allowing electron tunneling to form a conductive path. Thus, compared with a case where a high work function metal is required to form a metal-semiconductor junction in the related art, the photosensitive device ST can be formed in the present application by using the first conductive layer 25 of a conventional material, thereby improving the photosensitive performance of the photosensitive device ST.

It may be understood that, when a wiring space in the display panel 100 is limited, the photosensitive area of each of the first photosensitive element S1 and the second photosensitive element S2 can be relatively small in design, the light signal absorbed by each of the first photosensitive portion 271 and the second photosensitive portion 272 is relatively small, and the current signal generated thereby is relatively small. In some embodiments of the present application, one photosensitive device ST includes at least the first photosensitive element S1 and the second photosensitive element S2, which are designed in parallel, so that an overall photosensitive area of the photosensitive device ST is increased, the amount of the photoelectric signal is increased, and the detection sensitivity is improved.

It should be noted that, in the embodiments of the present application, that the photosensitive device ST includes at least two photosensitive elements (a first photosensitive element S1 and a second photosensitive element S2) connected in parallel is taken as an example for illustration, but cannot be understood as a limitation of the present application. For example, one photosensitive device ST may include three photosensitive elements, five photosensitive elements, or more in parallel.

In the embodiments of the present application, the switching element T further includes a first gate 253 and a first active portion 231. The first active portion 231 is provided corresponding to the first gate 253. The source 301 and the drain 302 are connected to the first active portion 231, respectively. The film structure of the first gate 253, the first active portion 231, the source 301, and the drain 302 will be illustrated in the following embodiments, of which details are not repeatedly described herein.

In the embodiments of the present application, the photosensitive device ST further includes at least one storage capacitor C. A first capacitor plate of the storage capacitor C is electrically connected to both the first electrode 251 and the second electrode 252. A second capacitor plate of the storage capacitor C is connected to either the source 301 or the drain 302.

For example, the photosensitive device ST includes only one storage capacitor C, and the first photosensitive element S1 and the second photosensitive element S2 share one storage element C, thereby further simplifying the structure of the photosensitive device ST.

Specifically, please refer to FIGS. 1-2, FIG. 2 is a schematic circuit diagram of a photosensitive device according to the present application. The photosensitive device ST includes a first photosensitive element S1, a second photosensitive element S2, a storage capacitor C, and a switching element T.

The first electrode 251 and the second electrode 252 are connected to a bias voltage VBias. When light enters the first photosensitive element S1 and the second photosensitive element S2 in the photosensitive device ST, the first photosensitive portion 271 in the first photosensitive element S1 and the second photosensitive portion 272 in the second photosensitive element S2 absorb light signals and convert the received light signals into electrical signals. The electric signals are stored in the storage capacitor C, and after the storage capacitor C is filled, the switching element T is turned on and the storage capacitor C is discharged, so that the signals generated by the first photosensitive element S1 and the second photosensitive element S2 can be transmitted to a detection signal line (not shown), via which the signals are transmitted to the corresponding circuits for processing, thereby realizing the detection of the light intensity.

In some embodiments of the present application, materials of the first active portion 231 may be a monocrystalline silicon, a low-temperature polycrystalline silicon, or a metal oxide semiconductor. The metal oxide semiconductor may be Indium Gallium Zinc Oxide (IGZO), Indium Gallium Zinc Tin Oxide (IGZTO), Indium Zinc Oxide (IZO), Indium Gallium Oxide (IGO), Indium Gallium Tin Oxide (IGTO), Indium Zinc Tin Oxide (IZTO), Indium Tin Oxide (ITO), Zinc Aluminum Tin Oxide (ATZO), Zinc Aluminum Indium Oxide (AIZO), or the like.

In some embodiments, the metal oxide semiconductor of the photosensitive layer 27 has an electron mobility greater than or equal to 10 cm²/Vs. Specifically, the materials of the first photosensitive portion 271 and the second photosensitive portion 272 are the IGZO. The IGZO has a high mobility. The IGZO has a good photosensitivity feature and a low resistance in the visible light band, so that the photosensitivity of the photosensitive device ST can be improved.

In some embodiments, the materials of the first active portion 231, the first photosensitive portion 271, and the second photosensitive portion 272 are all IGZO. Thus, the first photosensitive portion 271 and the second photosensitive portion 272 may be shared with an IGZO substrate film layer.

In some embodiments, the materials of the first active portion 231, the first photosensitive portion 271, and the second photosensitive portion 272 are different from each other. For example, the materials of the first photosensitive portion 271 and the second photosensitive portion 272 are indium zinc gallium oxide, and the material of the first active portion 231 may be monocrystalline silicon, low-temperature polycrystalline silicon, or other oxide semiconductor material other than IGZO. Thus, performance requirements of the switching element T, the first photosensitive element S1, and the second photosensitive element S2 can be simultaneously met.

In some embodiments, an orthographic projection of the first protection electrode 281 on the substrate 10 overlaps an orthographic projection of the first photosensitive portion 271 on the substrate 10, and an orthographic projection of the second protection electrode 282 on the substrate 10 overlaps an orthographic projection of the second photosensitive portion 272 on the substrate 10. Thus, the same photomask can be used for patterning to form the photosensitive layer 27 and the second conductive layer 28, thereby simplifying the process. Of course, the present application is not limited thereto.

In the embodiments of the present application, the second photosensitive element S2 is located on one side of the first photosensitive element S1 away from the drain 302. The first conductive layer 25 further includes a first capacitor electrode of the storage capacitor C. The first capacitor electrode is electrically connected to both the first electrode 251 and the second electrode 252. The third conductive layer 30 further includes a second capacitor electrode of the storage capacitor C. The second capacitor electrode is electrically connected to both the first protection electrode 281 and the second protection electrode 282. The second capacitor electrode at least partially overlaps the first capacitor electrode.

Specifically, the first capacitor electrode is a portion of the drain 302, and the second capacitor electrode is a portion of the first electrode 251. An orthographic projection of the drain 302 on the substrate 10 at least partially overlaps an orthographic projection of the first electrode 251 on the substrate 10. That is, the drain 302 is used with at least the first electrode 251 to constitute the storage capacitor C. Since the first electrode 251 is connected to the second electrode 252, the first photosensitive element S1 and the second photosensitive element S2 share the storage capacitor C.

In the embodiments of the present application, the display panel 100 further includes a first active layer 23 and a gate insulating layer 24. The first active layer 23 is disposed on one side of the first conductive layer 25 close to the substrate 10. The gate insulating layer 24 is disposed between the first active layer 23 and the first conductive layer 25. The first active layer 23 includes a first active portion 231. The first conductive layer 25 further includes a first gate 253. The first active portion 231 is provided corresponding to the first gate 253.

According to the embodiments of the present application, the first gate 253 is disposed at the same layer as the first electrode 251 and the second electrode 252, so that one photomask can be saved, and the process can be simplified. At the same time, the thickness of the display panel 100 is reduced.

In one embodiment, the display panel 100 further includes an interlayer insulating layer 29. The interlayer insulating layer 29 is located between the first conductive layer 25 and the third conductive layer 30. The interlayer insulating layer 29 has a first via hole 29a, a second via hole 29b, and a third via hole 29c. The first via hole 29a extends through the interlayer insulating layer 29 and to one side of the first active portion 231 away from the substrate 10. The source 301 is connected to the first active portion 231 through the first via hole 29a. The second via hole 29b extends through the interlayer insulating layer 29 and to one side of the first active portion 231 away from the substrate 10. The drain 302 is connected to the first active portion 231 through the second via hole 29b. The third via hole 29c exposes one side surface of the first protection electrode 281 away from the substrate 10. The drain 302 is connected to the first protection electrode 281 through the third via hole 29c.

The first active portion 231 includes a source region, a drain region, and a channel region (not shown) between the source region and the drain region. The source 301 is connected to the source region. The drain 302 is connected to the drain region. Since the source region and the drain region are conductive by ion doping or the like, the conductivity of the source 301 and the drain 302 as well as the first active portion 231 can be improved.

It should be noted that, in the embodiments of the present application, that the switching element T is used as a top-gate transistor is taken as an example for illustration, but cannot be understood as a limitation of the present application. In some embodiments of the present application, the switching element T may also be a bottom-gate transistor or a double gate transistor.

In the embodiments of the present application, the substrate 10 may include, but not limited to, a base substrate 11, a barrier layer 12, a first insulating layer 13, and a second insulating layer 14, which are sequentially stacked from bottom to top. The material of the base substrate 11 may be glass or a flexible material. The materials of the barrier layer 12, the first insulating layer 13, and the second insulating layer 14 may be silicon oxide, silicon nitride, or the like. The barrier layer 12, the first insulating layer 13, and the second insulating layer 14 may serve as water and oxygen barriers.

In the embodiments of the present application, the first conductive layer 25 is made of a material having high conductivity and a good light shielding property. For example, the material of the first conductive layer 25 may be molybdenum, titanium, molybdenum/copper (stack), molybdenum/titanium (stack), titanium/aluminum (stack), or the like. According to the embodiments of the present application, the first electrode 251 and the second electrode 252 are made of a conductive material having a light shielding property, so that the light incident from the substrate 10 onto the first photosensitive element S1 and the second photosensitive element S2 can be prevented, thereby improving the detection accuracy of the photosensitive device ST.

In the embodiments of the present application, the material of the insulating layer 26 may be silicon nitride, silicon oxide, or the like. The thickness of the insulating layer 26 is very thin, typically around 10 nm, such as 5 nm to 15 nm. When the first photosensitive element S1 and the second photosensitive element S2 are operated, electrons may pass through the first photosensitive element S1 and the second photosensitive element S2.

In the embodiments of the present application, the materials of the gate insulating layer 24 and the interlayer insulating layer 29 may be silicon oxide, silicon nitride, trialuminum oxide, and a stack thereof.

In the embodiments of the present application, the second conductive layer 28 is a transparent conductive material, so as to ensure that light can be incident onto the first photosensitive element S1 and the second photosensitive element S2 and improve the detection sensitivity of the photosensitive device ST. For example, the material of the second conductive layer 28 may be ITO, IZO, or the like.

In the embodiments of the present application, the display panel 100 further includes a fourth conductive layer 21 and a buffer layer 22. The fourth conductive layer 21 is disposed on one side of the first active layer 23 close to the substrate 10. The buffer layer 22 is disposed between the first active layer 23 and the fourth conductive layer 21. The fourth conductive layer 21 includes a light shielding portion 211. The light shielding portion 211 is provided corresponding to the first active unit 231. For example, an orthographic projection of the light shielding portion 211 on the substrate 10 at least covers an orthographic projection of the channel portion of the first active portion 231 on the substrate 10.

The light shielding portion 211 may block light incident from the substrate 10 in a direction away from the light shielding portion 211, thereby reducing interference of external light to the first active portion 231, and further improving the operation performance of the photosensitive device ST.

In some embodiments, the light shielding portion 211 may be further connected to either the source 301 or the drain 302 to form an equipotential, so that changes in the voltage on the light shielding portion 211 can be prevented from affecting the electrical performance of the first active portion 231.

In the embodiments of the present application, the third conductive layer 30 may further include an input electrode 303. The input electrode 303 is connected to either the first electrode 251 or the second electrode 252. The input electrode 303 is used to be connected to a bias voltage Vbias.

For example, the interlayer insulating layer 29 further includes a connection hole 29d. The connection hole 29d extends to one side surface of the second electrode 252 away from the substrate 10. The input electrode 303 is connected to the second electrode 252 through the connection hole 29d.

In the embodiments of the present application, the first conductive layer 25 further includes at least one scan line, which may be multiplexed in a time-division manner as the first electrode 251 and the second electrode 252. Time division multiplexing means that the scan line may be used to transmit a scan signal, or may be used as the first electrode 251 and the second electrode 252 to transmit a bias voltage Vbias. Specifically, the scan line is connected to a gate driving circuit and the signal line for supplying the bias voltage Vbias, respectively. When fingerprint recognition is performed, the signal line transmits the bias voltage Vbias to the scan line. When the display is performed, the gate driving circuit supplies the scan signal to the scan line.

Thus, the wiring in the display panel 100 can be reduced, and the sizes of the first photosensitive element S1 and the second photosensitive element S2 can be increased, thereby increasing the photosensitive area. it should be noted that, when a plurality of photosensitive devices ST are provided in the display panel 100, each scan line is multiplexed as only the first electrode 251 and the second electrode 252 connected to the first electrode 251 in one of the photosensitive devices ST.

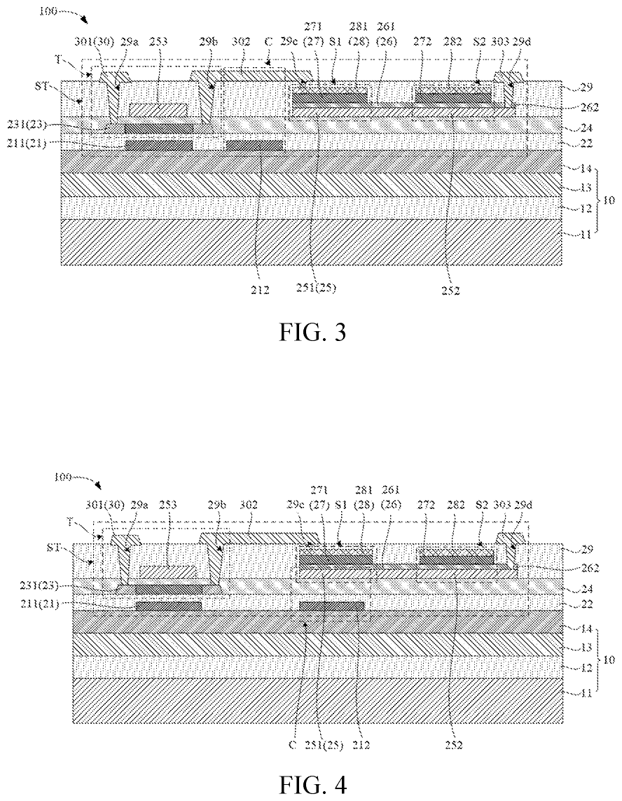

Please refer to FIG. 3, which is a schematic diagram of a second structure of a display panel according to the present application. A difference from the display panel 100 shown in FIG. 1 lies in that, in the embodiments of the present application, the display panel 100 includes a fourth conductive layer 21. The fourth conductive layer 21 includes a conductive portion 212. An orthographic projection of the conductive portion 212 on the substrate 10 at least partially overlaps an orthographic projection of the drain 302 on the substrate 10. That is, the conductive portion 212 is used along with the drain 302 to constitute the storage capacitor C.

In the embodiments of the present application, the conductive portion 212 is used along with the drain 302 to constitute the storage capacitor C, so that the length of the first electrode 251 can be reduced in the direction from the switching element T to the first photosensitive element S1. In such a case that the cross sectional area of the first electrode 251 is constant, the length of the first electrode 251 is reduced, thereby reducing the resistance of the first electrode 251 and reducing the load of the first photosensitive element S1 and the second photosensitive element S2.

Additionally, the fourth conductive layer 21 may further include a light shielding portion 211. The conductive portion 212 and the light shielding portion 211 are provided at the same layer, so that one photomask can be saved, and the process can be simplified. Of course, in some embodiments, the conductive portion 212 can be also provided at a different layer than the light shielding portion 211.

Please refer to FIG. 4, which is a schematic diagram of a third structure of a display panel according to the present application. A difference from the display panel 100 shown in FIG. 1 lies in that, in the embodiments of the present application, the fourth conductive layer 21 further includes a conductive portion 212. An orthographic projection of the conductive portion 212 on the substrate 10 at least partially overlaps an orthographic projection of the first electrode 251 and/or the second electrode 252 on the substrate 10. That is, the conductive portion 212 is used along with the first electrode 251 and/or the second electrode 252 to constitute the storage capacitor C.

It should be understood in the embodiments of the present application that the conductive portion 212 is used along with the first electrode 251 and/or the second electrode 252 to constitute the storage capacitor C, so that the extension length of the drain 302 from the switching element T to the first photosensitive element S1 can be reduced, thereby reducing the distance between the switching element T and the first photosensitive element S1 and reducing the wiring in the display panel 100. Since the conductive portion 212 is located below the first electrode 251 and/or the second electrode 252, the capacitance value of the storage capacitor C can be adjusted by adjusting the area of the conductive portion 212, so that no additional wiring space is occupied. As a result, the wiring space of the first photosensitive element S1 and the second photosensitive element S2 can be increased, the photosensitive area of the photosensitive device is further increased, and the sensitivity is improved.

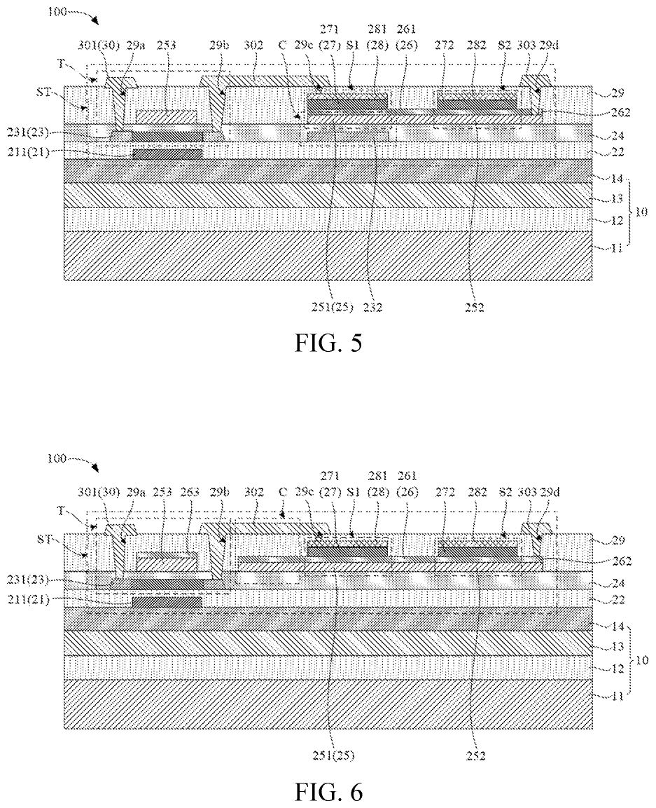

Please refer to FIG. 5, which is a schematic diagram of a fourth structure of a display panel according to the present application. A difference from the display panel 100 shown in FIG. 1 lies in that, in the embodiments of the present application, the first active layer 23 includes a first active portion 231 and a conductive electrode portion 232.

The first active portion 231 is provided corresponding to the first gate 253. The source 301 and the drain 302 are connected to the first active portion 231, respectively. An orthographic projection of the electrode portion 232 on the substrate 10 partially overlaps an orthographic projection of the first electrode 251 and/or the second electrode 252 on the substrate 10.

The electrode portion 232 may be subjected to a conductive processing by a process such as ion doping to improve the conductivity of the electrode portion 232.

In the embodiments of the present application, the conductive electrode portion 232 is used along with the first electrode 251 and/or the second electrode 252 to constitute the storage capacitor C. On one hand, it is possible to reduce the distance between the switching element T and the first photosensitive element S1, reduce the wiring in the display panel 100, and increase the wiring space of the first photosensitive element S1 and the second photosensitive element S2, thereby further improving the photosensitive area of the photosensitive device, and improving the sensitivity. On the other hand, since only the buffer layer 22 is provided between the electrode portion 232 and the first electrode 251 (the second electrode 252), the distance between two electrode plates of the storage capacitor C is reduced, thereby increasing the capacitance value of the storage capacitor C.

Please refer to FIG. 6, which is a schematic diagram of a fifth structure of a display panel according to the present application. A difference from the display panel 100 shown in FIG. 1 lies in that, in the embodiments of the present application, the insulating layer 26 further includes a third insulating portion 263. An orthographic projection of the first insulating portion 261 and the second insulating portion 262 on the substrate 10 overlaps an orthographic projection of the first electrode 251 and the second electrode 252 on the substrate 10. An orthographic projection of the third insulating portion 263 on the substrate 10 overlaps an orthographic projection of the first gate 253 on the substrate 10.

Patterning of the first conductive layer 25 and the insulating layer 26 can be realized in the embodiments of the present application by using the same photomask, thereby simplifying the process. Further, since the first insulating portion 261 covers the first electrode 251 and the second electrode 252, and the third insulating portion 263 covers the first gate 253, the insulating layer 26 can protect the first electrode 251, the second electrode 252, and the first gate 253 when the photosensitive layer 27 is formed, thereby improving the stability of the photosensitive device.

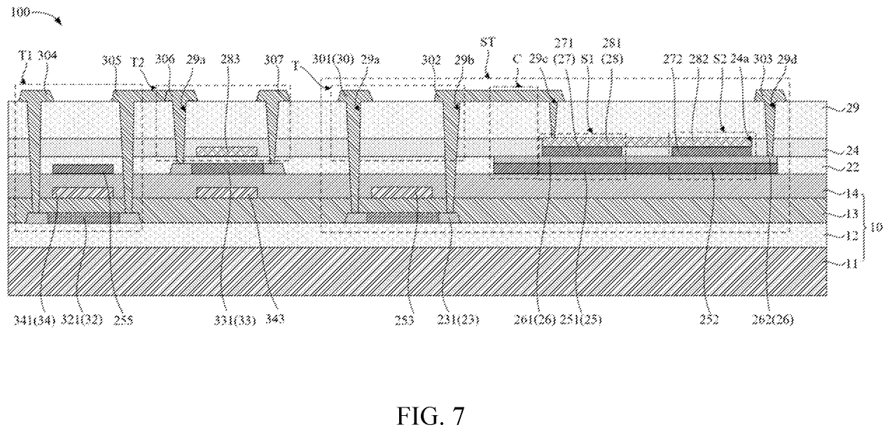

Please refer to FIG. 7, which is a schematic diagram of a sixth structure of a display panel according to the present application. A difference from the display panel 100 shown in FIG. 1 lies in that, in the embodiments of the present application, the display panel 100 further includes a pixel driving circuit. The pixel driving circuit further includes a first driving transistor T1 and a second driving transistor T2.

The display panel 100 further includes a second active layer 32, a third active layer 33, and a conductive layer 34.

The second active layer 32 is disposed between the substrate 10 and the photosensitive layer 27. The second active layer 32 includes a second active portion 321 of the first driving transistor T1. The second active portion 321 includes a polysilicon semiconductor.

The third active layer 33 is disposed between the second active layer 32 and the photosensitive layer 27. The third active layer 33 includes a third active portion 331 of the second driving transistor T2. The third active portion 331 includes a metal oxide semiconductor.

The conductive layer 34 is disposed between the second active layer 32 and the third active layer 33. The conductive layer 34 includes a second gate 341 of the first driving transistor T1. The second gate 341 at least partially overlaps the second active portion 321.

The second conductive layer 28 further includes a third gate 283 of the second driving transistor T2. The third gate 283 at least partially overlaps the third active portion 331.

In some embodiments of the present application, still referring to FIG. 7, the first active portion 231 includes a polysilicon semiconductor. The second active layer 32 further includes a first active portion 231. The conductive layer 34 further includes a first gate 253 of the switching element T. The first gate 253 at least partially overlaps the first active portion 231. That is, the first active layer 23 and the second active layer 32 are the same active layer.

The first conductive layer 25 further includes a third electrode 255. The third electrode 255 and the second gate 341 are used along with the first insulating layer 13 between the third electrode 255 and the second gate 341 to constitute a capacitor. The conductive layer 34 further includes a fifth gate 343 of the second driving transistor T2, that is, the second driving transistor T2 is of a double gate structure.

The third conductive layer 30 further includes a first source 304 and a first drain 305 of the first driving transistor T1, and a second source 306 and a second drain 307 of the second driving transistor T2. The first drain 305 may be connected to the second source 306 by a via hole.

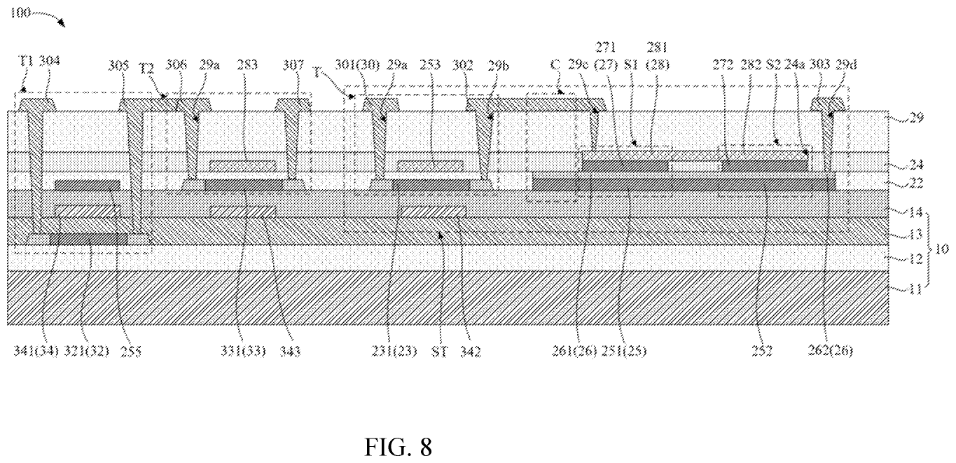

In some embodiments, please refer to FIG. 8, which is a schematic diagram of a seventh structure of a display panel according to the present application. A difference from the display panel 100 shown in FIG. 7 lies in that, in the embodiments of the present application, the first active layer 231 includes a metal oxide semiconductor. The third active layer 33 further includes a first active portion 231.

The conductive layer 34 further includes a fourth gate 342 of the switching element T. The second conductive layer 28 further includes a first gate 253 of the switching element T. The fourth gate 342 at least partially overlaps the first active portion 231. The first gate 253 at least partially overlaps the first active portion 231. That is, the switching element T is of a double gate structure.

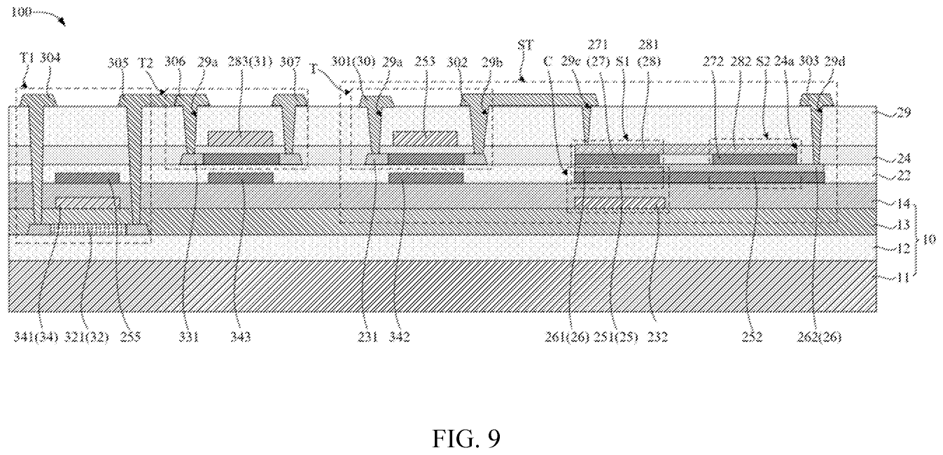

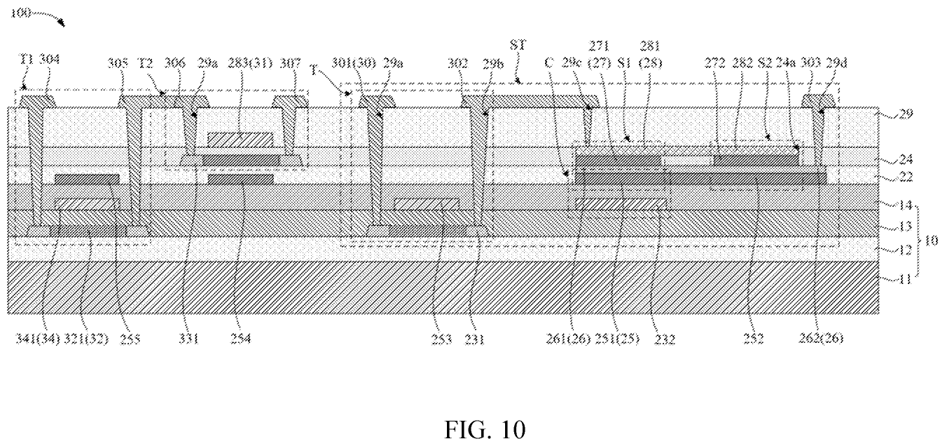

Please refer to FIG. 9, which is a schematic diagram of an eighth structure of a display panel according to the present application. A difference from the display panel 100 shown in FIG. 1 lies in that, in the embodiments of the present application, the photosensitive layer 27 further includes a first active portion 231 of the switching element T. The gate insulating layer 24 has an opening 24a. The opening 24a exposes one side surface of the first photosensitive portion 271 and the second photosensitive portion 272 away from the substrate 10. The first protection electrode 281 and the second protection electrode 282 are provided within the opening 24a.

In some embodiments of the present application, the first active portion 231, the first photosensitive portion 271, and the second photosensitive portion 272 are provided at the same layer, which can simplify the manufacturing process. At the same time, the gate insulating layer 24 is formed, and then the first protection electrode 281 and the second protection electrode 282 are formed, so that damage to the first active portion 231 can be avoided when the second conductive layer 28 is patterned, thereby improving the stability of the switching element T.

Further, in some embodiments, still referring to FIG. 9, the display panel 100 further includes a pixel circuit. The pixel circuit includes a first driving transistor T1 and a second driving transistor T2.

The photosensitive layer 27 further includes a first active portion 231 of the switching element T and a third active portion 331 of the second driving transistor T2. The first active portion 231 of the switching element T, the third active portion 331 of the second driving transistor T2, the first photosensitive portion 271, and the second photosensitive portion 272 are provided in the same layer.

Specifically, the display panel 100 further includes a second active layer 32, a conductive layer 34, and a fifth conductive layer 31. The second active layer 32 is disposed between the substrate 10 and the photosensitive layer 27. The conductive layer 34 is disposed between the second active layer 32 and the photosensitive layer 27. The fifth conductive layer 31 is disposed on one side of the gate insulting layer 24 away from the substrate 10. The second active layer 32 includes a second active portion 321 of the first driving transistor T1. The second active portion 321 includes a polysilicon semiconductor. The conductive layer 34 includes a second gate 341 of the first driving transistor T1 and an electrode portion 232. The second gate 341 at least partially overlaps the second active portion 321. The fifth conductive layer 31 further includes a first gate 253 of the switching element T and a third gate 283 of the second driving transistor T2.

The first conductive layer 25 further includes a fourth gate 342 of the switching element T, a fifth gate 343 of the second driving transistor T2, and a third electrode 255. The third conductive layer 30 further includes a first source 304 and a first drain 305 of the first driving transistor T1, and a second source 306 and a second drain 307 of the second driving transistor T2. The first drain 305 may be connected to the second source 306 by a via hole.

Please refer to FIG. 10, which is a schematic diagram of a ninth structure of a display panel according to the present application. A difference from the display panel 100 shown in FIG. 9 lies in that, in the embodiments of the present application, the second active portion 321 of the first driving transistor T1 and the first active portion 231 of the switching element T are provided in the same layer. The third active portion 331 of the second driving transistor T2, the first photosensitive portion 271, and the second photosensitive portion 272 are provided in the same layer.

Specifically, the second active layer 32 includes a second active portion 321 of the first driving transistor T1 and a first active portion 231 of the switching element T. The conductive layer 34 includes a second gate 341 of the first driving transistor T1 and a first gate 253 of the switching element T.

The embodiments of the present application employ Low Temperature Poly-Oxide (LTPO) technology, which can reduce power consumption of the display panel 100. Meanwhile, the switching element T and the photosensitive device ST are manufactured in the same process as the in-plane LTPO structure, so that the thickness of the display panel 100 can be reduced, and the manufacturing process can be simplified.

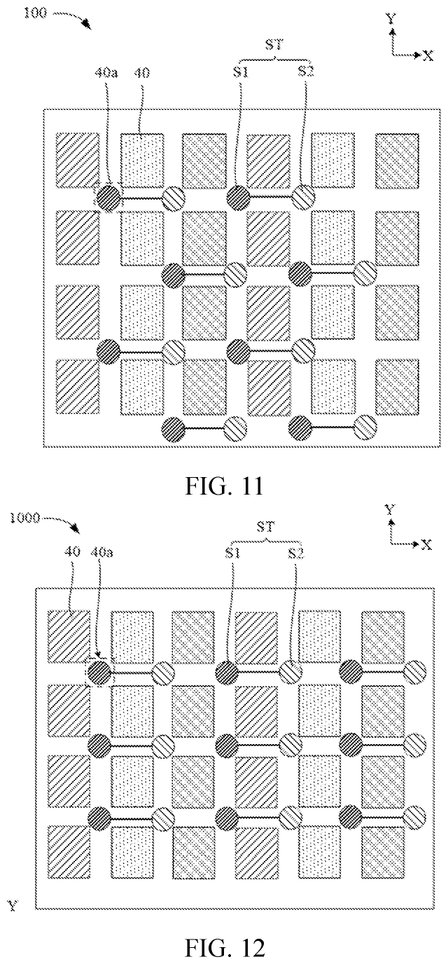

Please refer to FIG. 11, which is a first plan view of a display panel according to the present application. The display panel 100 further includes a plurality of light emitting units 40. The plurality of light emitting units 40 are arranged in a plurality of rows in a first direction Y, and are arranged in a plurality of columns in a second direction X. The first direction Y intersects the second direction X. For example, the first direction Y is perpendicular to the second direction X.

A plurality of intersecting regions 40a are formed between the plurality of rows of light emitting units 40 and the plurality of columns of light emitting units 40. Each of the intersecting regions 40a is provided with at most one first photosensitive element S1 or one second photosensitive elements S2.

In the embodiments of the present application, the first photosensitive element S1 and the second photosensitive element S2 are disposed in different intersecting regions 40a so that the first photosensitive element S1 and the second photosensitive element S2 are both staggered from the light emitting unit 40 to avoid affecting the display effect of the display panel. Further, by disposing the first photosensitive element S1 and the second photosensitive element S2 in different intersecting regions 40a, the wiring space of the first photosensitive element S1 and the second photosensitive element S2 can be increased, and the photosensitive area of the first photosensitive element S1 and the second photosensitive element S2 can be increased, thereby further increasing the amount of the electric signal.

In the embodiment of the present application, each of the intersection regions 40a may be provided with the first photosensitive element S1 or the second photosensitive element S2 to improve test sensitivity. Of course, the distribution densities of the first photosensitive element S1 and the second photosensitive element S2 may be set according to actual product requirements.

As shown in FIG. 11, the first photosensitive element S1 and the second photosensitive element S2 are located in two adjacent ones of the intersecting regions 40a, respectively. The two adjacent intersecting regions 40a are located on the same side of the same light emitting unit 40.

As a result, the distance between the first photosensitive element S1 and the second photosensitive element S2 in the same photosensitive device ST can be reduced, thereby facilitating parallel connection between the first photosensitive element S1 and the second photosensitive element S2 and reducing the wiring length.

In some embodiments of the present application, the display panel 100 includes a plurality of photosensitive devices ST. A plurality of first photosensitive elements S1 and a plurality of second photosensitive elements S2 in the same row are alternately arranged. A plurality of first photosensitive elements S1 and a plurality of second photosensitive elements S2 in the same column are alternately arranged. Each of the first photosensitive elements S1 is connected in parallel with one of the second photosensitive elements S2, which is located in the same row and in the same side as the first photosensitive element and adjacent to the first photosensitive element. Alternatively, each of the first photosensitive elements S1 is connected in parallel with one of the second photosensitive elements S2, which is located in the same column and in the same side as the first photosensitive element and adjacent to the first photosensitive element.

For example, as shown in FIG. 11, each of the first photosensitive elements S1 is connected in parallel with one of the second photosensitive elements S2, which is located in the same row as the first photosensitive element S1 and located at the right of the first photosensitive element S1 and adjacent to the first photosensitive element S1. Of course, each of the first photosensitive elements S1 may be also connected in parallel with one of the second photosensitive elements S2, which is located in the same row as the first photosensitive element S1 and located at the left of the first photosensitive element S1 and adjacent to the first photosensitive element S1.

It should be understood that the embodiments of the present application enable the plurality of photosensitive devices ST to be staggered in the display panel 100, the distribution of the plurality of photosensitive devices ST in the display panel 100 is more uniform, and the uniformity of the detection sensitivity of the display panel 100 can be improved.

In some embodiments of the present application, as shown in FIG. 12, a plurality of first photosensitive elements S1 and a plurality of second photosensitive elements S2 located in the same row are alternately arranged, and the first photosensitive elements S1 or the second photosensitive elements S2 are located in the same column. Each of the first photosensitive elements S1 is connected in parallel with one of the second photosensitive elements S2, which is located in the same row and in the same side as the first photosensitive element and adjacent to the first photosensitive element.

It should be understood that the embodiments of the present application make the positional relationship of the first photosensitive element S1 and the second photosensitive element S2 in each of the photosensitive devices ST identical, thereby improving the structural regularity of the plurality of photosensitive devices S and reducing the process difficulty.

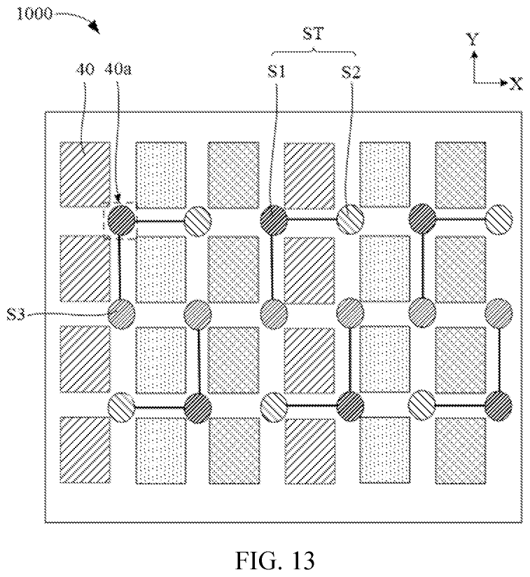

In some embodiments of the present application, as shown in FIGS. 1 and 13, the photosensitive device ST further includes a third photosensitive element S3 (not shown in FIG. 1).

The third photosensitive element S3 includes a third electrode, a third protection electrode, and a third photosensitive portion between the third electrode and the third protection electrode. The third electrode, the first electrode 251 and the second electrode 252 are located at the same layer and connected to each other. The third photosensitive portion, the first photosensitive portion 271, and the second photosensitive portion 272 are located at the same layer and disposed at intervals. The third protection electrode, the first protection electrode 281, and the second protection electrode 282 are located at the same layer. The third protection electrode is connected to the source 301 or the drain 302.

The first photosensitive element S1, the second photosensitive element S2, and the third photosensitive element S3 are respectively located in three ones of the intersection regions 40a at three vertices of the same light emitting unit.

Specifically, in the same column of the light emitting units 40, for any two adjacent ones of the photosensitive devices ST, two first photosensitive elements S1 are arranged diagonally, two second photosensitive elements S2 are arranged diagonally, and two third photosensitive elements S3 are located in the same row, thereby improving the distribution uniformity of the plurality of photosensitive devices ST.

The embodiments of the present application provide that the photosensitive device ST includes a first photosensitive element S1, a second photosensitive element S2, and a third photosensitive element S3, thereby further improving the photosensitive area of the photosensitive device ST. By arranging the first photosensitive element S1, the second photosensitive element S2, and the third photosensitive element S3 in three ones of the intersecting regions 40a at three vertices of the same light emitting unit 40, respectively, it is possible to reduce the distance between any two ones of the first photosensitive element S1, the second photosensitive element S2, and the third photosensitive element S3 in the same photosensitive device ST, thereby facilitating parallel connection between any two ones of the first photosensitive element S1, the second photosensitive element S2, and the third photosensitive element S3, and reducing the wiring length.

The display panels provided in the embodiments of the present application are described in detail above. A specific example is used herein to describe a principle and an implementation of the present application. The description of the foregoing embodiments is merely used to help understand a method and a core idea of the present application. In addition, an ordinary person skilled in the art may make changes in a specific implementation manner and an application scope according to an idea of the present application. In conclusion, content of this specification should not be construed as a limitation on the present application.

What is claimed is:

1. A display panel, comprising: at least one photosensitive device, the at least one photosensitive device including a switching element, a first photosensitive element, and a second photosensitive element;
wherein the display panel further comprises:
a substrate;
a first conductive layer disposed on the substrate and including a first electrode and a second electrode connected to the first electrode;
a photosensitive layer disposed on one side of the first conductive layer away from the substrate and including a first photosensitive portion corresponding to the first electrode and a second photosensitive portion corresponding to the second electrode, wherein the first photosensitive portion and the second photosensitive portion are disposed at intervals, and the photosensitive layer further includes a metal oxide semiconductor;
an insulating layer disposed between the first conductive layer and the photosensitive layer;
a second conductive layer disposed on one side of the photosensitive layer away from the substrate and including a first protection electrode and a second protection electrode, wherein the first protection electrode is electrically connected to the first photosensitive portion, and the second protection electrode is electrically connected to the second photosensitive portion; and
a third conductive layer disposed on one side of the second conductive layer away from the substrate and including a source and a drain of the switching element, wherein the first protection electrode and the second protection electrode are both electrically connected to the source or the drain of the switching element;
wherein the first photosensitive element includes the first electrode, the first photosensitive portion, and the first protection electrode, and the second photosensitive element includes the second electrode, the second photosensitive portion, and the second protective electrode.

2. The display panel of claim 1, further comprising:
a first active layer disposed between the substrate and the first conductive layer and including a first active portion of the switching element, wherein the source and the drain of the switching element are electrically connected to the first active portion, respectively.

3. The display panel of claim 2, wherein the photosensitive device further includes:
a storage capacitor including a first capacitor electrode and a second capacitor electrode at least partially overlapping the first capacitor electrode;
the first capacitor electrode is electrically connected to both the first electrode and the second electrode; and
the second capacitor electrode is electrically connected to both the first protection electrode and the second protection electrode, and at least partially overlaps the first capacitor electrode.

4. The display panel of claim 3, further comprising: a fourth conductive layer including a conductive portion, wherein an orthographic projection of the conductive portion on the substrate at least partially overlaps an orthographic projection of at least one of the first electrode and the second electrode on the substrate.

5. The display panel of claim 3, wherein the metal oxide semiconductor of the photosensitive layer has an electron mobility greater than or equal to 10 cm²/Vs, and the insulating layer has a thickness of 5 nm to 15 nm.

6. The display panel of claim 2, further comprising: a pixel driving circuit including both a first driving transistor and a second driving transistor;
wherein the display panel further comprises:
a second active layer disposed between the substrate and the photosensitive layer and including a second active portion of the first driving transistor, wherein the second active portion includes a polysilicon semiconductor;
a third active layer disposed between the second active layer and the photosensitive layer and including a third active portion of the second driving transistor, wherein the third active portion includes a metal oxide semiconductor; and
a conductive layer disposed between the second active layer and the third active layer and including a second gate of the first driving transistor, wherein the second gate at least partially overlaps the second active portion;
wherein the second conductive layer further includes a third gate of the second driving transistor, the third gate at least partially overlapping the third active portion.

7. The display panel of claim 6, wherein the first active portion includes a polysilicon semiconductor; and
the second active layer further includes the first active portion, and the conductive layer further includes a first gate of the switching element, the first gate at least partially overlapping the first active portion.

8. The display panel of claim 6, wherein the first active portion includes a metal oxide semiconductor; and
the third active layer further includes the first active portion, the conductive layer further includes a fourth gate of the switching element, and the second conductive layer further includes a first gate of the switching element, wherein the fourth gate at least partially overlaps the first active portion, and the first gate at least partially overlaps the first active portion.

9. The display panel of claim 1, further comprising: a plurality of light emitting units arranged in a plurality of rows in a first direction and arranged in a plurality of columns in a second direction;
wherein a plurality of intersecting regions are formed between the plurality of rows of light emitting units and the plurality of columns of light emitting units, and each of the intersecting regions is provided with at most one first photosensitive element or one second photosensitive elements.

10. The display panel of claim 9, wherein the first photosensitive element and the second photosensitive element are respectively located in two adjacent ones of the intersecting regions located on the same side of the same light emitting unit.

11. The display panel of claim 10, further comprising: a plurality of the photosensitive devices;
wherein a plurality of the first photosensitive elements and a plurality of the second photosensitive elements in the same row are alternately arranged, a plurality of the first photosensitive elements and a plurality of the second photosensitive elements in the same column are alternately arranged, and each of the first photosensitive elements is connected in parallel with one of the second photosensitive elements, which is located in the same row and in the same side as the first photosensitive element and adjacent to the first photosensitive element, or each of the first photosensitive elements is connected in parallel with one of the second photosensitive elements, which is located in the same column and in the same side as the first photosensitive element and adjacent to the first photosensitive element; or
a plurality of the first photosensitive elements and a plurality of the second photosensitive elements in the same row are alternately arranged, the first photosensitive elements or the second photosensitive elements are in the same column, and each of the first photosensitive elements is connected in parallel with one of the second photosensitive elements, which is located in the same row and in the same side as the first photosensitive element and adjacent to the first photosensitive element.

12. The display panel of claim 9, wherein the photosensitive device further includes a third photosensitive element;
wherein the third photosensitive element includes a third electrode, a third protection electrode, and a third photosensitive portion between the third electrode and the third protection electrode; the third electrode and the first electrode are located in the same layer and connected to each other, the third photosensitive portion and the first photosensitive portion are located in the same layer and arranged at intervals, and the third protection electrode is connected to either the source or the drain; and
the first photosensitive element, the second photosensitive element, and the third photosensitive element are respectively located in three of the intersection regions at three vertices of the same light emitting unit.

13. A display panel, comprising: at least one photosensitive device, the at least one photosensitive device including a switching element, a first photosensitive element, and a second photosensitive element;
wherein the display panel further comprises:
a substrate;
a first conductive layer disposed on the substrate and including a first electrode and a second electrode connected to the first electrode;
a photosensitive layer disposed on one side of the first conductive layer away from the substrate and including a first photosensitive portion corresponding to the first electrode and a second photosensitive portion corresponding to the second electrode, wherein the first photosensitive portion and the second photosensitive portion are disposed at intervals, and the photosensitive layer further includes a metal oxide semiconductor;
an insulating layer disposed between the first conductive layer and the photosensitive layer;
a second conductive layer disposed on one side of the photosensitive layer away from the substrate and including a first protection electrode and a second protection electrode, wherein the first protection electrode is electrically connected to the first photosensitive portion, and the second protection electrode is electrically connected to the second photosensitive portion; and
a third conductive layer disposed on one side of the second conductive layer away from the substrate and including a source and a drain of the switching element, wherein the first protection electrode and the second protection electrode are both electrically connected to the source or the drain of the switching element;
wherein the first photosensitive element includes the first electrode, the first photosensitive portion, and the first protection electrode, and the second photosensitive element includes the second electrode, the second photosensitive portion, and the second protective electrode;
wherein the display panel further comprises:
a first active layer disposed between the substrate and the first conductive layer and including a first active portion of the switching element, wherein the source and the drain of the switching element are electrically connected to the first active portion;
wherein the display panel further comprises: a plurality of light emitting units arranged in a plurality of rows in a first direction and arranged in a plurality of columns in a second direction;
wherein a plurality of intersecting regions are formed between the plurality of rows of light emitting units and the plurality of columns of light emitting units, and each of the intersecting regions is provided with at most one first photosensitive element or one second photosensitive elements.

14. The display panel of claim 13, wherein the photosensitive device further includes: a storage capacitor including a first capacitor electrode and a second capacitor electrode at least partially overlapping the first capacitor electrode;
the first capacitor electrode is electrically connected to both the first electrode and the second electrode; and
the second capacitor electrode is electrically connected to both the first protection electrode and the second protection electrode, and at least partially overlapping the first capacitor electrode.

15. The display panel of claim 14, further comprising: a fourth conductive layer including a conductive portion, wherein an orthographic projection of the conductive portion on the substrate at least partially overlaps an orthographic projection of at least one of the first electrode and the second electrode on the substrate.

16. The display panel of claim 14, wherein the metal oxide semiconductor of the photosensitive layer has an electron mobility greater than or equal to 10 cm²/Vs, and the insulating layer has a thickness of 5 nm to 15 nm.

17. The display panel of claim 13, further comprising: a pixel driving circuit including both a first driving transistor and a second driving transistor;
wherein the display panel further comprises:
a second active layer disposed between the substrate and the photosensitive layer and including a second active portion of the first driving transistor, wherein the second active portion includes a polysilicon semiconductor;
a third active layer disposed between the second active layer and the photosensitive layer and including a third active portion of the second driving transistor, wherein the third active portion includes a metal oxide semiconductor; and
a conductive layer disposed between the second active layer and the third active layer and including a second gate of the first driving transistor, wherein the second gate at least partially overlaps the second active portion;
wherein the second conductive layer further includes a third gate of the second driving transistor, the third gate at least partially overlapping the third active portion.

18. The display panel of claim 17, wherein the first active portion includes a polysilicon semiconductor; and
the second active layer further includes the first active portion, and the conductive layer further includes a first gate of the switching element, the first gate at least partially overlapping the first active portion.

19. The display panel of claim 17, wherein the first active portion includes a metal oxide semiconductor; and
the third active layer further includes the first active portion, the conductive layer further includes a fourth gate of the switching element, and the second conductive layer further includes a first gate of the switching element, wherein the fourth gate at least partially overlaps the first active portion, and the first gate at least partially overlaps the first active portion.

20. The display panel of claim 13, wherein the first photosensitive element and the second photosensitive element are respectively located in two adjacent ones of the intersecting regions located on the same side of the same light emitting unit.
